(19) United States
(12) Patent Application Publication
(10) Pub. No.: US 2009/0004818 A1
(43) Pub. Date: Jan. 1, 2009

(54) Method of Fabricating Flash Memory Device

(75) Inventors: Seung Woo Shin, Kyeongki-do (KR); Eun Soo Kim, Incheon (KR); Suk Joong Kim, Kyeongki-do (KR); Jong Hye Cho, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Incheon-si (KR)

(21) Appl. No.: 11/956,865

(22) Filed: Dec. 14, 2007

(30) Foreign Application Priority Data
Jun. 28, 2007 (KR) 10-2007-0064438

(51) Int. Cl. H01L 21/762

(52) U.S. Cl. 438/435; 257/E21.546

(57) ABSTRACT

Disclosed herein is a method of fabricating a semiconductor flash memory device, which method avoids and prevents damage to the conductive layer of a floating gate. The disclosed method can prevent a reduction in the charge trap density characteristics and improve the yield of the device.

### CROSS REFERENCE TO RELATED APPLICATION

The priority of Korean patent application No. 2007-64438 filed Jun. 28, 2007, the disclosure of which is incorporated herein by reference in its entirety, is claimed.

### BACKGROUND OF THE INVENTION

1. Field of the Disclosure

The disclosure generally relates to a method of fabricating a flash memory device, and, more particularly, relates to a method of fabricating a flash memory device, which avoids and prevents damage to a conductive layer for a floating gate.

2. Brief Description of Related Technology

A memory cell array of a flash memory device includes a plurality of memory cell strings. Each memory cell string includes a plurality of memory cells and select transistors. An isolation layer is formed between the strings to separate the memory cells formed in each memory cell string in a string unit.

Generally, an isolation layer is formed on a semiconductor substrate. Thereafter, a memory cell is formed. The memory cell has a stack structure consisting of a tunnel insulating layer, a floating gate, a dielectric layer and a control gate. Gate patterning process have become difficult because of the increasingly high integration of semiconductor memory devices. More specifically, as these devices have become more highly integrated, gate widths and the distance between the gates have been reduced. A self-aligned shallow trench isolation (hereinafter, referred to as “self-aligned STI”) scheme has been developed to try to address this difficulty.

According to the self-aligned STI scheme, a tunnel insulating layer and a floating gate conductive layer are formed on a semiconductor substrate, and an isolation layer is simultaneously formed when a patterning process is performed so that it is possible to prevent an alignment error between the floating gate and the isolation area. More specifically, when fabricating a flash memory device, a tunnel insulating layer, a first conductive layer for a floating gate, a buffer layer and an etching stop layer are sequentially formed on a semiconductor substrate. The etching stop layer, the buffer layer, the first conductive layer, and the tunnel insulating layer are sequentially patterned with a mask having patterns and an opening corresponding to an isolation area, and the exposed semiconductor substrate is etched to form a trench. An insulating layer for an isolation layer is formed in, and completely fills, the trench. This insulating layer may be formed of an oxide layer obtained by performing an oxidation process.

In particular, where the insulating layer is formed of a high density plasma (HDP) layer, an exposed surface of the first conductive layer can be rapidly oxidized. An oxidized portion of the first conductive layer is removed when an etching process for the isolation layer is performed and, as a result, the first conductive layer may be damaged by the etching process. Subsequent etching processes may cause further damage to the first conductive layer. Accordingly, such damage to the first conductive layer can cause the flash memory device to fail.

### SUMMARY OF THE INVENTION

Disclosed herein is a method of fabricating a flash memory device. The method generally includes providing a semiconductor substrate, the substrate having an active area on which a tunnel insulating layer and a first conductive layer are laminately formed, and an isolation area on which a trench is formed. The method also includes forming a first insulating layer in the trench, forming a protective layer along surfaces of the first conductive layer and the first insulating layer to protect the first conductive layer, and forming a second insulating layer on the first insulating layer to form an isolation layer.

Furthermore, in various preferred embodiments, the method also includes etching the second insulating layer, and forming a third insulating layer on the un-etched portions of the second insulating layer. Still further, in preferred embodiments, the method also includes forming an etching stop layer on the first conductive layer, and forming a buffer layer between the etching stop layer on the first conductive layer. In further preferred embodiments, the method includes removing the etching stop layer after forming the isolation layer, forming a dielectric layer along surfaces of the first conductive layer and the isolation layer, and forming a second conductive layer on the dielectric layer.

Additional features of the invention may become apparent to those skilled in the art from a review of the following detailed description, taken in conjunction with the drawings, and the appended claims.

### BRIEF DESCRIPTION OF THE DRAWINGS

The above and other features and advantages of the present invention will become readily apparent by reference to the following detailed description when considered in conjunction with the accompanying drawings wherein:

FIGS. 1A to 1G are sectional views of a flash memory device that, together, illustrate a method of fabricating a flash memory device according to an embodiment of the present invention; and,

FIGS. 2A to 2G are sectional views of a flash memory device that, together, illustrate another embodiment of the method.

While the disclosed method is susceptible of embodiments in various forms, there are illustrated in the drawings (and will hereafter be described) specific embodiments of the invention, with the understanding that the disclosure is intended to be illustrative, and is not intended to limit the invention to the specific embodiments described and illustrated herein.

### DESCRIPTION OF SPECIFIC EMBODIMENTS

Disclosed herein is a method of fabricating a flash memory device. The method generally includes providing a semiconductor substrate, the substrate having an active area on which a tunnel insulating layer and a first conductive layer are laminately formed, and an isolation area on which a trench is formed. The method also includes forming a first insulating layer in the trench, forming a protective layer along surfaces of the first conductive layer and the first insulating layer to protect the first conductive layer, and forming a second insulating layer on the first insulating layer to form an isolation layer. Furthermore, in various preferred embodiments, the method also includes etching the second insulating layer, and forming a third insulating layer on the un-etched portions of the second insulating layer. Still further, in preferred embodiments, the method also includes forming an etching stop layer on the first conductive layer, and forming a buffer layer between the etching stop layer on the first conductive layer. In further preferred embodiments, the method includes removing the etching stop layer after forming the isolation layer, forming a dielectric layer along surfaces of the first conductive layer and the isolation layer, and forming a second conductive layer on the dielectric layer.

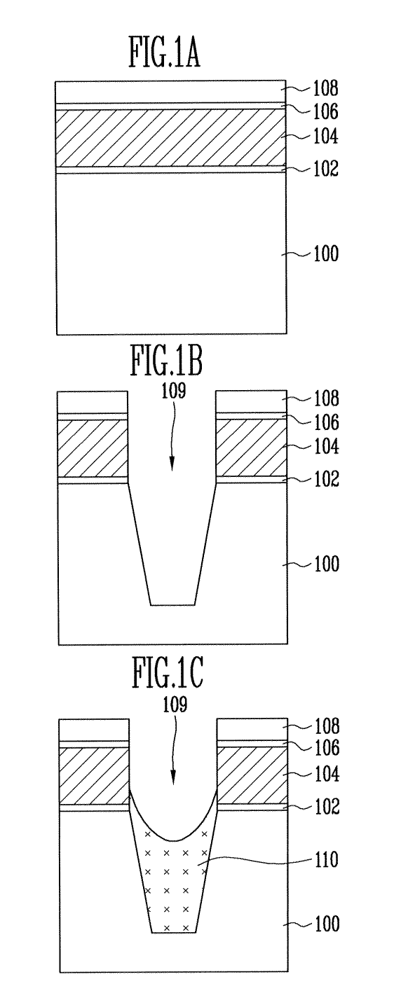

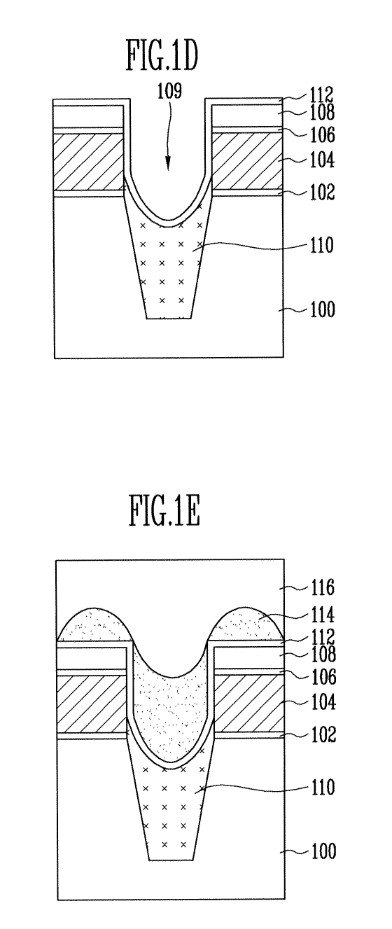

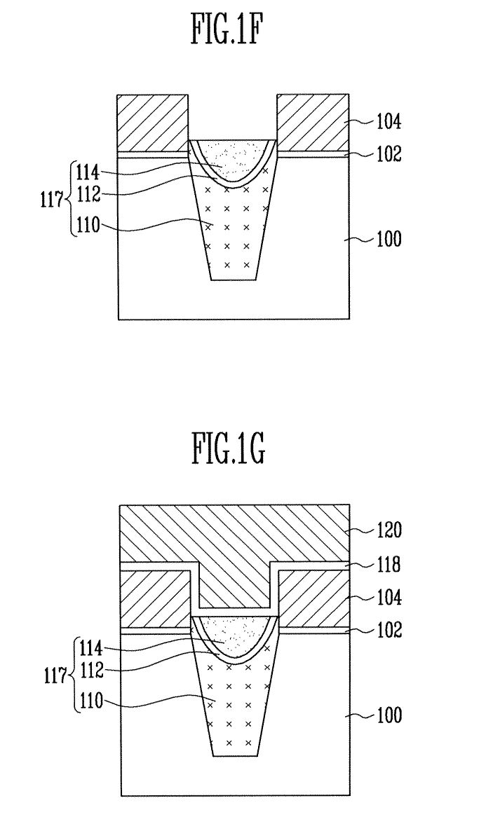

FIGS. 1A to 1G are sectional views of a flash memory device that, together, illustrate a method of fabricating a flash memory device according to an embodiment of the present invention. Referring to FIG. 1A, a tunnel insulating layer 102, a first conductive layer 104 for a floating gate, a buffer layer 106 for protecting the first conductive layer 104, and an etching stop layer 108 are sequentially formed on a semiconductor substrate 100. Preferably, the tunnel insulating layer 102 is formed of an oxide layer, obtained by performing an oxidation process, the first conductive layer 104 preferably is formed of a polysilicon layer, the buffer layer 106 preferably is formed of an oxide layer, and the etching stop layer 108 preferably is formed of a nitride layer.

Referring to FIG. 1B, a mask pattern (not shown) having an opening corresponding to an isolation area is formed on the etching stop layer 108, and an etching process is carried out according to the mask pattern (not shown) to pattern the etching stop layer 108, the buffer layer 106, the first conductive layer 104 and the tunnel insulating layer 102. The exposed semiconductor substrate 100 is then etched to form a trench 109. Subsequently, the mask pattern (not shown) is removed. Although not shown in FIG. 1B, after the trench 109 is formed, an insulating layer (not shown) may be formed along a surface of the semiconductor substrate 100, where the trench 109 is formed, to protect the trench 109 and a surface of the first conductive layer 104.

Referring to FIG. 1C, a first insulating layer 110 for an isolation layer is formed to fill a lower portion of the trench 109. It is preferable that the first insulating layer 110 has a dual-layered structure consisting of an oxide layer or single-layered structure of a flowable oxide layer. For example, because the flowable oxide layer can be formed of a spin on glass (SOG) layer, it is easy to fill a lower portion of the trench 109. Subsequently, a wet etching process is carried out to remove the first insulating layer 110. However, a portion of the first insulating layer 110 filling the lower portion of the trench 109 remains. Due to the above process, an aspect ratio of the trench 109 can be lowered. Portions of side walls of the first conductive layer 104 are exposed by the etching process so that the first insulating layer 110 has U-shaped section, and the first insulating layer preferably has a certain depth for preventing the tunnel insulating layer 102 from being exposed.

Referring to FIG. 1D, to prevent an oxidization of the first conductive layer 104, a protective layer 112 is formed along a surface of the semiconductor substrate 100 on which the first conductive layer 104 is formed. More specifically, the protective layer 112 is formed atop the first insulating layer in the trench 109, along the sidewalls defining the trench 109, and atop the etching stop layer 108. In addition, the protective layer 112 may be formed for preventing a surface of the first conductive layer 104 from being damaged during a subsequent web etching process. Accordingly, the protective layer 112 preferably is formed of an oxide layer. On the other hand, the protective layer 112 may be formed of an oxide layer and a nitride layer, or it may be formed by oxidizing a surface of the nitride layer after forming the nitride layer. In particular, it is preferable that the oxide layer is formed through a radical oxidation process or a chemical vapor deposition (CVD) method. Because a rapid oxidation reaction is not generated in the radical oxidation process, it is possible to stably form the protective layer 112 on a surface of the first conductive layer 104. The CVD method can be performed at a temperature of 600° C. to 800° C. However, the CVD method preferably is performed at a temperature of 750° C. to 800° C. if a gaseous mixture of dichlorosilane (SiH₂Cl₂:DCS) gas and dinitrogen monoxide (N₂O) gas is utilized. The CVD method preferably is performed at a temperature of 730° C. to 780° C. if a gaseous mixture of silane (SiH₄) gas and dinitrogen monoxide (N₂O) gas is utilized, and preferably at a temperature of 600° C. to 700° C. if the protective layer is formed of an oxide layer, which oxide layer is formed by dissolving TEOS (tetra ethyl ortho silicate) gas.

The protective layer 112 is easily removed in a subsequent etching process to expose the first conductive layer 104. Accordingly, to prevent removal of the protective layer and exposure of the first conductive layer, a heat treatment process is subsequently performed for the semiconductor substrate 100 on which the protective layer 112 is formed. The heat treatment process enhances the density of the protective layer 112 to reduce an etching ratio of the protective layer 112 in the subsequent etching process. The heat treatment process is performed at a temperature of 850° C. to 900° C. for at least 30 minutes, preferably 30 minutes to 60 minutes. The protective layer 112 should have a thickness sufficient to prevent oxidation of the first conductive layer 104 in a subsequent process for forming a high density plasma (HDP) oxide layer. Preferably, the protective layer 112 has a thickness of at least 30 Å. However, the maximum thickness of the protective layer should be determined in view of the formation of the HDP oxide layer. For example, the protective layer 112 desirably has a thickness of 30 Å to 100 Å.

Referring to FIG. 1E, a second insulating layer 114 for an isolation layer is formed. Preferably, the second insulating layer 114 is formed of a HDP layer. When the process for forming the second insulating layer 114 is performed, an over hang in which the insulating layer formed on the etching stop layer 108 is thicker than that formed in a lower portion of the trench (109 in FIG. 1D) is formed so that it is difficult to fill completely the trench (109 in FIG. 1D) with the insulating layer. Accordingly, an etching process is performed after forming the second insulating layer 114 to remove a portion of the second insulating layer 114 formed thickly on the etching stop layer 108, whereby a subsequent gap fill process can be easily carried out. Subsequently, a third insulating layer 116 for an isolation layer is formed. Preferably, the third insulating layer 116 is formed of a HDP layer. Like this, although the second insulating layer 114 and the third insulating layer 116 are formed by performing repeatedly the process of forming an insulating layer and the etching process, the first conductive layer 104 is protected by the protective layer 112 so that it is possible to prevent the first conductive layer 104 from being oxidized.

Referring to FIG. 1F, a polishing process (for example, a chemical mechanical polishing (CMP) process) is performed to expose the etching stop layer (108 in FIG. 1E. The etching stop layer (108 in FIG. 1E) and the buffer layer (106 in FIG. 1E) are then removed. An etching process is carried out for adjusting an effective field oxide height (EFH) of an isolation layer 117.

Since the etching process for adjusting an EFH of the isolation layer 117 is the process of removing an oxide layer, even the protective layer 112 formed on a surface of the conductive layer 104 is removed. However, as described above with respect to FIG. 1E, in the process of forming the isolation layer 117, the protective layer 112 prevents the first conductive layer 104 from being oxidized, and so it is possible to prevent a loss of the first conductive layer 104.

Referring to FIG. 1G, a dielectric layer 118 is formed along surfaces of the isolation layer 117 and the first conductive layer 104, and a second conductive layer 120 for a control gate is then formed on the dielectric layer 118.

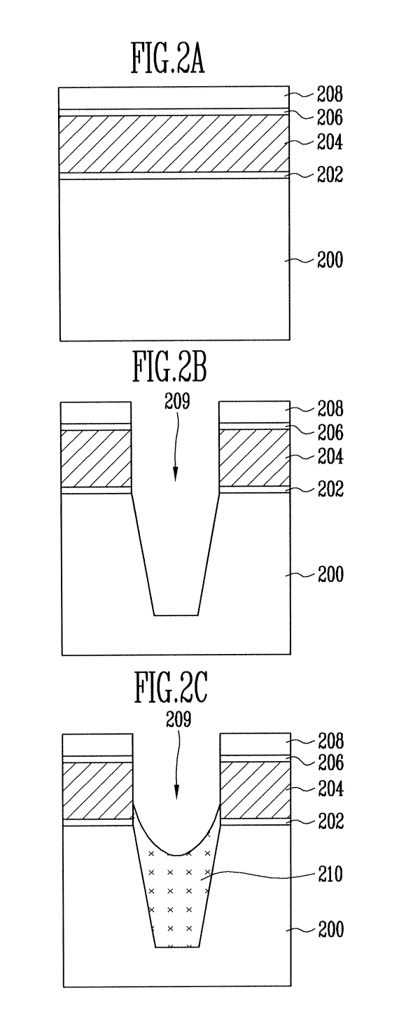

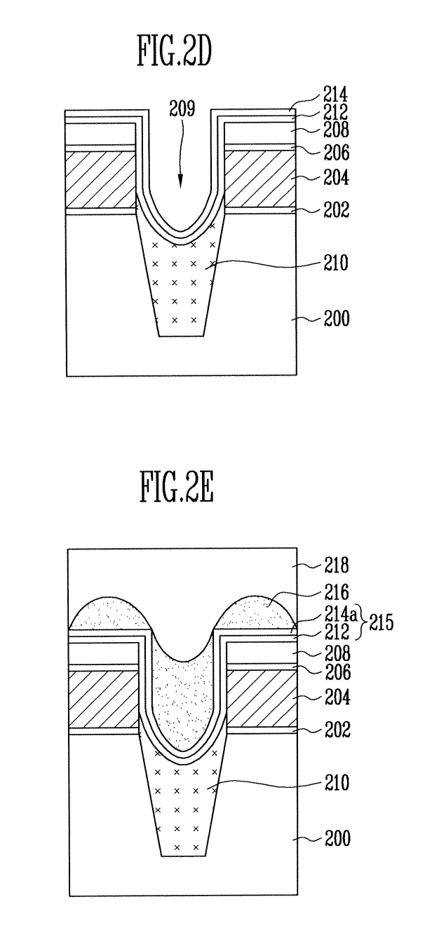

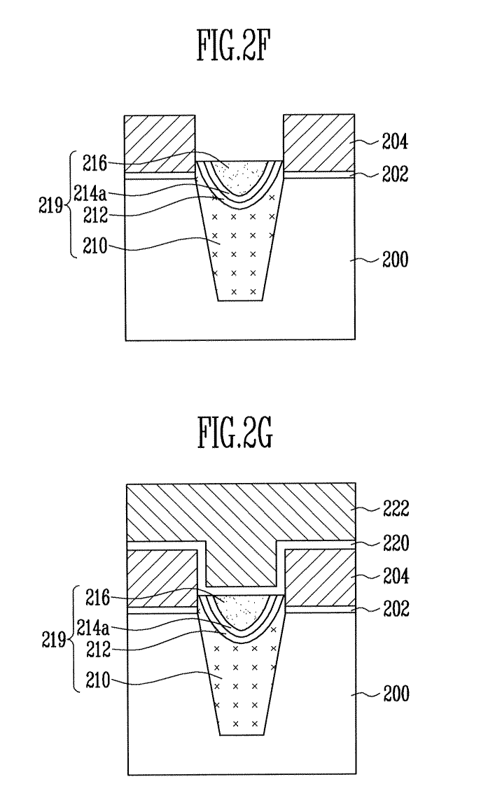

FIGS. 2A to 2G are sectional views of a flash memory device that, together, illustrate another embodiment of the method of fabricating a flash memory device.

Referring to FIG. 2A, a tunnel insulating layer 202, a first conductive layer 204 for a floating gate, a buffer layer 206 for protecting the first conductive layer 204, and an etching stop layer 208 are sequentially formed on a semiconductor substrate 200. Preferably, the tunnel insulating layer 202 is formed of an oxide layer obtained by performing an oxidation process, the first conductive layer 204 preferably is formed of a polysilicon layer, the buffer layer 206 preferably is formed of an oxide layer, and the etching stop layer 208 preferably is formed of a nitride layer.

Referring to FIG. 2B, a mask pattern (not shown) having an opening corresponding to an isolation area is formed on the etching stop layer 208, and an etching process is carried out according to the mask pattern (not shown) to pattern the etching stop layer 208, the buffer layer 206, the first conductive layer 204 and the tunnel insulating layer 202. The exposed semiconductor substrate 200 is then etched to form a trench 209. Subsequently, the mask pattern (not shown) is removed. Although not shown in FIG. 2C, after the trench 209 is formed, an insulating layer (not shown) may be formed along a surface of the semiconductor substrate 200, where the trench 209 is formed, to protect the trench 209 and a surface of the first conductive layer 204.

Referring to FIG. 2C, a first insulating layer 210 for an isolation layer is formed to fill a lower portion of the trench 209. It is preferable that the first insulating layer 210 has a dual-layered structure consisting of an oxide layer and a flowable oxide layer or a single-layered structure of a flowable oxide layer. For example, because the flowable oxide layer can be formed of a SOG layer having an excellent flowability, it is easy to fill a lower portion of the trench 209. Subsequently, a wet etching process is carried out to remove the first insulating layer 210. However, a portion of the first insulating layer 210 filling the lower portion of the trench 209 remains. Because the flowable oxide layer has excellent flowability, it is easy to fill a lower portion of the trench 209 with the flowable oxide layer, and so an aspect ratio of the trench 209 can be lowered. A portion of the first conductive layer 204 is exposed by an etching process for the first insulating layer 210. More specifically, portions of side walls of the first conductive layer 204 are exposed by the etching process so that the first insulating layer 210 has a U-shaped section, and the first insulating layer preferably has a certain depth for preventing the tunnel insulating layer 202 from being exposed.

Referring to FIG. 2D, to prevent an oxidization of the first conductive layer 204, a first protective layer 212 is formed along a surface of the semiconductor substrate 200 on which the first conductive layer 204 is formed. More specifically, the first protective layer 212 is formed atop the first insulating layer 210 in the trench 209, along side walls defining the trench 209, and atop the etching stop layer 208. Preferably, the first protective layer 212 is formed of an oxide layer, and has a thickness of 10 Å to 100 Å. In particular, the oxide layer preferably is formed through a radical oxidation process or a CVD method. Because a rapid oxidation reaction is not generated in the radical oxidation process, it is possible to stably form the first protective layer 212 on a surface of the first conductive layer 204. The CVD method can be performed at a temperature of 600° C. to 800° C. However, the CVD method preferably is performed at a temperature of 750° C. to 800° C. if a gaseous mixture of dichlorosilane (SiH₂Cl₂:DCS) gas and dinitrogen monoxide (N₂O) gas is utilized. The CVD method preferably is performed at a temperature of 730° C. to 780° C. if gaseous mixture of silane (SiH₄) gas and dinitrogen monoxide (N₂O) gas is utilized, and preferably at a temperature of 600° C. to 700° C. if the first protective layer is formed of an oxide layer, which oxide layer is formed by dissolving TEOS gas.

Thereafter, a second protective layer 214 is further formed along a surface of the first protective layer 212. Preferably, the second protective layer 214 is formed of a nitride layer having an oxidation resistance which is relatively higher than that of an oxide layer in a process of forming the HDP oxide layer. The nitride layer preferably has a thickness of at least 30 Å. However, the second protective layer 214 is formed such that portions of the second protective layers 214 formed on side walls defining the trench 209 and facing each other do not contact one another. For example, the second protective layer 214 preferably has a thickness of 30 Å to 100 Å. Preferably, the second protective layer is formed by a CVD method at a temperature of 650° C. to 750° C., and can utilize a gaseous mixture of dichlorosilane (SiH₂Cl₂:DCS) gas and ammonia (NH₃) gas or a gaseous mixture of silane (SiH₄) gas and ammonia (NH₃) gas.

Referring to FIG. 2E, an insulating layer for an isolation layer is formed. When the insulating layer is formed, it is difficult to fill the trench (209 in FIG. 2D) without generating voids, and it is therefore desirable to form the insulating layer through a plurality of processes. For example, a second insulating layer 216 is formed on the semiconductor substrate 200 on which the second protective layer (214 in FIG. 2D) is formed. Preferably, the second insulating layer 216 is formed of a HDP oxide layer. In particular, in the process of forming the second insulating layer 216, the second protective layer (214 in FIG. 2D), which preferably is the nitride layer, is converted into a second protective layer 214a which is an oxide of the nitride layer. The above phenomenon is caused by an oxidation in the process of forming the HDP oxide layer, and the first and second protective layers 212 and 214a are oxidized in place of the first conductive layer 204 so that the above protective layers can protect the first conductive layer 204. Due to the above phenomenon, the first and second protective layers 212 and 214a become an oxide layer 215.

After the second insulating layer 216 is formed, an etching process for removing the overhanged second insulating layer 216 formed thickly on the etching stop layer 208 is performed. Like this, by performing repeatedly the process for forming the insulating layer and the etching process, it is possible to lower an aspect ratio of the trench (209 in FIG. 2D). Subsequently, a third insulating layer 218 for the isolation layer is formed. It is preferable that the third insulating layer 218 is formed of an oxide layer.

As described above, when the processes for forming the second insulating layer 216 and the third insulating layer 218 are performed, the first conductive layer 204 is protected by the first and second protective layers 212 and 214 so that a surface of the first conductive layer 204 is not oxidized any more.

Referring to FIG. 2F, a polishing process (for example, a CMP process) is performed to expose the etching stop layer (208 in FIG. 2E). The etching stop layer (208 in FIG. 2E) and the buffer layer (206 in FIG. 2E) are then removed. Subsequently, an etching process is carried out for adjusting an EFH of an isolation layer 219.

Because the etching process for adjusting the EFH of the isolation layer 219 is the process of removing an oxide layer, even the first and second protective layers 212 and 214a formed on a surface of the conductive layer 204 are removed. However, as described above with respect to FIG. 2E, because the first and second protective layers 212 and 214a have inhibited the first conductive layer 204 from being oxidized in the process of forming the isolation layer 219, it is possible to prevent a loss of the first conductive layer 204.

Referring to FIG. 2G, a dielectric layer 220 is formed along surfaces of the isolation layer 219 and the first conductive layer 204, and a second conductive layer 222 for a control gate is then formed on the dielectric layer 220.

By forming the protective layer(s) on a surface of the conductive layer for the floating gate, it is possible to prevent damage to the conductive layer when performing a process of forming the insulating layer for the isolation layer. Therefore, the present invention can prevent a reduction in the charge trap density characteristics so that a yield of the semiconductor device can be improved.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a flash memory device, the method comprising:
providing a semiconductor substrate having an active area, on which a tunnel insulating layer and a first conductive layer are laminately formed, and an isolation area on which a trench is formed;
forming a first insulating layer in the trench;
forming a protective layer along surfaces of the first conductive layer and the first insulating layer to protect the first conductive layer; and,
forming a second insulating layer on the first insulating layer to form an isolation layer.

2. The method of claim 1, wherein the protective layer is formed of an oxide layer.

3. The method of claim 1, wherein the protective layer is (i) formed of an oxide layer and a nitride layer, or (ii) formed by forming a nitride layer and then oxidizing a surface of the nitride layer.

4. The method of claim 2 further comprising performing a radical oxidation process to form the oxide layer.

5. The method of claim 2 further comprising performing a chemical vapor deposition (CVD) method to form the oxide layer.

6. The method of claim 5, wherein the CVD method utilizes a gaseous mixture of (i) dichlorosilane (SiH₂Cl₂:DCS) gas and dinitrogen monoxide (N₂O) gas, (ii) silane (SiH₄) gas and dinitrogen monoxide (N₂O) gas, or (iii) tetra ethyl ortho silicate (TEOS) gas, while heat is supplied.

7. The method of claim 3, wherein the nitride layer has a thickness of 30 Å to 100 Å.

8. The method of claim 3, wherein the nitride layer is formed through a CVD method.

9. The method of claim 8, wherein the CVD method is performed at a temperature of 650° C. to 750° C., and utilizes gaseous mixture of dichlorosilane (SiH₂Cl₂:DCS) gas and ammonia (NH₃) gas, or a gaseous mixture of silane (SiH₄) gas and ammonia (NH₃) gas.

10. The method of claim 3, wherein the nitride layer is converted into an oxide layer at the time of forming the second insulating layer.

11. The method of claim 1 further comprising the step of performing a heat treatment process after forming the protective layer.

12. The method of claim 11, wherein the heat treatment process is performed at a temperature of 850° C. to 900° C. for 30 to 60 minutes.

13. The method of claim 1, wherein the first insulating layer is formed of a flowable oxide layer.

14. The method of claim 13, wherein the flowable oxide layer is formed of a spin on glass (SOG) layer.

15. The method of claim 1 further comprising, after forming the second insulating layer, performing an etching process to lower an aspect ratio.

16. The method of claim 15 further comprising, after performing the etching process, forming a third insulating layer on the un-etched portions of the second insulating layer.

17. The method of claim 1, wherein the second layer and the third insulating layer each have a density greater than that of the first insulating layer.

18. The method of claim 17, wherein the second and third insulating layers are formed of a high density plasma (HDP) oxide layer.

19. The method of claim 1, wherein the step of providing the semiconductor substrate further comprises forming an etching stop layer on the first conductive layer.

20. The method of claim 19 further comprising the step of forming a buffer layer between the first conductive layer and the etching stop layer.

21. The method of claim 20, wherein the buffer layer is formed of an oxide layer.

22. The method of claim 19, further comprising:
removing the etching stop layer after the step of forming the isolation layer;
forming a dielectric layer along surfaces of the first conductive layer and the isolation layer; and,
forming a second conductive layer on the dielectric layer.
